(19) United States
(12) Patent Application Publication
(10) Pub. No.: US 2026/0186536 A1
(43) Pub. Date: Jul. 2, 2026

(54) DISPLAY MODULE AND DISPLAY APPARATUS

(71) Applicants: Chengdu BOE Optoelectronics Technology Co., Ltd., Chengdu, Sichuan, (CN); BOE TECHNOLOGY GROUP CO., LTD., Beijing (CN)

(72) Inventors: Xin LI, Beijing (CN); Xu LU, Beijing (CN); Liang GAO, Beijing (CN); Huinan SHI, Beijing (CN); Yang YANG, Beijing (CN); Xuan ZHANG, Beijing (CN)

(21) Appl. No.: 18/861,663

(22) PCT Filed: Nov. 2, 2023
(86) PCT No.: PCT/CN2023/129269

§ 371 Date: Oct. 30, 2024

(51) Int. Cl. G06F 1/16

(52) U.S. Cl. CPC G06F 1/1656; G06F 1/1641; G06F 1/1652

(57) ABSTRACT

A display module and a display apparatus are provided. The display module includes a cover plate, a first adhesive layer, a display panel, a second adhesive layer and a support layer-which are stacked together. The display panel-includes a first non-foldable region, a first foldable region and a second non-foldable region. The support layer-includes a first region corresponding to the first foldable region of the display panel and a second region-on opposite sides of the first region. In a first direction, the first region at least partially has a first thickness and the second region at least partially has a second thickness, the first thickness is less than the second thickness. The display module effectively avoids crack and imprint of the support layer at the first region due to the fact that a bending region of the flexible display module is bent several times.

### TECHNICAL FIELD

The present disclosure relates to the field of display technology, and in particular to a display module and a display apparatus.

### BACKGROUND

With the development of display technology, a display apparatus has a more and more extensive use, and a flexible display apparatus is popular with the public. The flexible display apparatus has the characteristics of being relatively light, thin, highly flexible and the like, and can realize different applications such as folding, curling and the like.

At present, a flexible display module of a product in a flexible form is required to realize functions such as bending and the like due to bending requirements for the product. A metal support member on the back of a display panel is limited by a material, so that the metal support member may be designed with a through hole region, a half-etching region and the like in a bending region of the metal support member. However, such the design may reduce strength of the bending region of the flexible display module, which causes defects, such as imprint, crack for the bending region of the support member and lines made by folding and the like after the flexible display module is bent several times.

### SUMMARY

The embodiment of the present disclosure provides a flexible display module and a flexible display apparatus, which are used for obtaining a display module and a display apparatus with a support layer with different thicknesses in a bending region and a non-bending region, so that the risk of generating an imprint, and the risk of the crack, the lines or the like at the bending region of the support layer due to the fact that the flexible display module is bent several times are reduced. The technical scheme is as follows:
In one aspect of the embodiments of the present disclosure, there is provided a flexible display module, including: a cover plate; a display panel, including a first non-foldable region, a first foldable region, and a second non-foldable region, wherein the first non-foldable region and the second non-foldable region are on opposite sides of the first foldable region; a first adhesive layer between the cover plate and the display panel; a second adhesive layer on a side of the display panel away from the cover plate; and a support layer on a side of the second adhesive layer away from the display panel, wherein the support layer includes a first region corresponding to the first foldable region of the display panel and a second region on opposite sides of the first region, the first region at least partially has a first thickness, and the second region at least partially has a second thickness; wherein the first thickness is less than the second thickness in a first direction, and the first direction is perpendicular to a plane where the display panel is located.

In some embodiments, the first region includes a first concave portion therein.

In some embodiments, the first region further includes a second concave portion therein on a side of the support layer opposite to the side where the first concave portion is located in the first direction.

In some embodiments, the support layer further includes a second concave portion on the second surface.

In some embodiments, a distance between a bottom of the first concave portion and a surface of the support layer away from the first concave portion in the first direction is the first thickness; or a distance between the bottom of the first concave portion and a bottom of the second concave portion in the first direction is the first thickness.

In some embodiments, the first thickness is greater than or equal to one fifth of the second thickness; and the first thickness is less than or equal to one half of the second thickness.

In some embodiments, the flexible display module further includes a first filling layer in the first concave portion.

In some embodiments, the flexible display module further includes a second filling layer in the second concave portion.

In some embodiments, the first foldable region is folded inward, the first concave portion is on a side of the support layer away from the display panel, and the first filling layer is made of one or more of a pressure sensitive adhesive, an optical adhesive and a foam.

In some embodiments, the first foldable region is folded inward, the second concave portion is on a side of the support layer close to the display panel, and the second filling layer is made of one or more of polyimide and polyethylene terephthalate.

In some embodiments, the support layer further includes a transition region between the first region and the second region; and the transition region includes first openings therein, and an orthographic projection of each first opening on the support layer forms an opening pattern.

In some embodiments, a distance between a bottom of each first opening and a side of the support layer away from each first opening in the first direction is a third thickness; the third thickness is greater than or equal to one half of the second thickness; and the third thickness is less than or equal to two thirds of the second thickness.

In some embodiments, the transition region further including second openings on a side opposite to the side where the first openings are located, and an orthographic projection of each second opening on the support layer forms the opening pattern.

In some embodiments, a distance between the bottom of each first opening and a bottom of a second opening corresponding to the first opening in the first direction is a third thickness; the third thickness is greater than or equal to one half of the second thickness; and the third thickness is less than or equal to two thirds of the second thickness.

In some embodiments, the orthographic projection of each first opening on the support layer and the orthographic projection of each second opening on the support layer form the same opening pattern.

In some embodiments, the first opening includes at least one opening pattern, and a pattern of an orthographic projection of the opening pattern on the support layer is one or more of rectangular, wavy, and arc-shaped.

In some embodiments, a cross section of each first opening has a shape from one or more of rectangular, square, and trapezoidal.

In some embodiments, the at least one opening pattern extends along a second direction and has a first length in the second direction, and adjacent opening patterns are spaced apart from each other in a third direction.

In some embodiments, the first length is the same as a length of the support layer in the second direction.

In some embodiments, the first length is greater than or equal to one quarter of the length of the support layer in the second direction; and the first length is less than or equal to one half of the length of the support layer in the second direction.

In some embodiments, the first opening and the second opening corresponding to each other are symmetrical in the first direction.

In some embodiments, the first openings and the second openings are staggered in the first direction.

In some embodiments, the support layer includes a first support layer, a second support layer, and a third adhesive layer, the second support layer is on a side of the first support layer away from the display panel, and the second support layer is adhered to the first support layer by the third adhesive layer.

In some embodiments, the first region includes a third concave portion therein on a side of the second support layer away from the first support layer.

In some embodiments, a distance between a surface of the second support layer away from the first support layer and a surface of the first support layer close to the display panel in the first direction is the second thickness.

In some embodiments, the flexible display module further includes a third filling layer in the third concave portion; and the first foldable region is folded inwards, and the third filling layer is made of one or more of a pressure sensitive adhesive, an optical adhesive and a foam.

In some embodiments, the second region of the second support layer includes first opening grooves therein symmetrical with respect to the first region in a third direction.

In some embodiments, the flexible display module further includes a fourth filling layer in each first opening groove, wherein the fourth filling layer is made of one or more of graphite, a heat conductive adhesive, and a copper sheet.

In some embodiments, the display panel further includes a second foldable region and a third non-foldable region, the second foldable region is between the second non-foldable region and the third non-foldable region, and the first foldable region has a width greater than that of the second foldable region in a third direction; and the support layer includes a third region corresponding to the second foldable region, the third region at least partially has a fourth thickness, and the fourth thickness is less than the second thickness.

In some embodiments, the third region includes a fourth concave portion therein, and a distance between a bottom of the fourth concave portion and a surface of the support layer away from the fourth concave portion in the first direction is the fourth thickness; the first thickness is greater than the fourth thickness.

In some embodiments, the display panel is folded with a first radius of curvature in the first foldable region, the display panel is folded with a second radius of curvature in the second foldable region; and the first radius of curvature is greater than the second radius of curvature.

In some embodiments, the flexible display module further includes a first filling layer in the first concave portion, wherein the first concave portion is on a side of the support layer away from the display panel; a fifth filling layer in the fourth concave portion, wherein the fourth concave portion is on a side of the support layer away from the display panel; wherein a modulus of the first filling layer is greater than that of the fifth filling layer.

In some embodiments, the flexible display module further includes a polarizer on a side of the display panel away from the support layer.

In another aspect of the embodiments of the present disclosure, a flexible display apparatus is provided, where the flexible display apparatus includes the flexible display module in any one of the above embodiments.

In the flexible display module provided by the embodiments of the present disclosure, the support layer is located on a side of the second adhesive layer away from the display panel, and has the first region corresponding to the first foldable region of the display panel and the second region on opposite sides of the first region, the first region at least partially has the first thickness, the second region at least partially has the second thickness, and the first thickness is less than the second thickness in the direction from the support layer to the display panel and perpendicular to a plane where the display panel is located, so that the support layer with unequal thickness in the first region and the second region is formed, and the support layer is maintained as a whole in the first region. On one hand, the support layer is designed with unequal thickness in the first region and the second region, so that the risk of the crack and the lines made by folding for the first region of the support layer after the bending region of the flexible display module is bent several times is effectively reduced while the bending performance of the flexible display module is ensured. On the other hand, hollow holes are unnecessarily formed in the first region of the support layer through an additional process, so that a dustproof effect can be achieved for the first region of the support layer while the method of forming the support layer is simplified.

### BRIEF DESCRIPTION OF DRAWINGS

In order to more clearly illustrate the technical solutions in the embodiments of the present disclosure, the drawings required to be used in the description of the embodiments are briefly introduced below. Obviously, the drawings in the description below are only some embodiments of the present disclosure, and it is obvious for one of ordinary skill in the art that other drawings may be obtained according to the drawings without creative efforts.

FIG. 1 is a cross-sectional view of a structure of a flexible display module in the related art;

FIG. 2 is a cross-sectional view of a structure of a flexible display module according to an embodiment of the present disclosure;

FIG. 3 is a schematic diagram of a structure of a support layer according to an embodiment of the present disclosure;

FIG. 4 is a cross-sectional view of another structure of a flexible display module according to an embodiment of the present disclosure;

FIG. 5 is a schematic diagram of another structure of a support layer according to an embodiment of the present disclosure;

FIG. 6 is a cross-sectional view of another structure of a flexible display module according to an embodiment of the present disclosure;

FIG. 7 is a schematic diagram of another structure of a support layer according to an embodiment of the present disclosure;

FIG. 8 is a schematic diagram of another structure of a support layer according to an embodiment of the present disclosure;

FIG. 9 is a cross-sectional view of another structure of a flexible display module according to an embodiment of the present disclosure;

FIG. 10 is a cross-sectional view of another structure of a flexible display module according to an embodiment of the present disclosure;

FIG. 11 is a cross-sectional view of another structure of a flexible display module according to an embodiment of the present disclosure;

FIG. 12 is a cross-sectional view of another structure of a flexible display module according to an embodiment of the present disclosure;

FIG. 13 is a schematic diagram of a bent flexible display module according to an embodiment of the present disclosure;

FIG. 14 is a schematic diagram of another structure of a support layer according to an embodiment of the present disclosure;

FIG. 15 is a cross-sectional view of another structure of a flexible display module according to an embodiment of the present disclosure;

FIG. 16 is a cross-sectional view of another structure of a flexible display module according to an embodiment of the present disclosure;

FIG. 17 is a cross-sectional view of another structure of a flexible display module according to an embodiment of the present disclosure;

FIG. 18a is a schematic diagram of a first opening according to an embodiment of the present disclosure;

FIG. 18b is a schematic cross-sectional view along a line A-A of FIG. 18a;

FIG. 19a is a schematic diagram of another first opening according to an embodiment of the present disclosure;

FIG. 19b is a schematic cross-sectional view along a line A-A of FIG. 19a;

FIG. 20a is a schematic diagram of yet another first opening according to an embodiment of the present disclosure;

FIG. 20b is a schematic cross-sectional view along a line A-A of FIG. 20a;

FIG. 21 is a cross-sectional view of still another structure of a flexible display module according to an embodiment of the present disclosure;

FIG. 22 is a schematic diagram of yet another structure of a support layer according to an embodiment of the present disclosure;

FIG. 23 is a cross-sectional view of still another structure of a flexible display module according to an embodiment of the present disclosure;

FIG. 24 is a schematic diagram of yet another structure of a support layer according to an embodiment of the present disclosure;

FIG. 25 is a cross-sectional view of still another structure of a flexible display module according to an embodiment of the present disclosure;

FIG. 26 is a cross-sectional view of still another structure of a flexible display module according to an embodiment of the present disclosure;

FIG. 27 is a cross-sectional view of still another structure of a flexible display module according to an embodiment of the present disclosure;

FIG. 28 is a schematic diagram of a display module in a three-fold form according to an embodiment of the present disclosure; and

FIG. 29 is another schematic diagram of a display module in a three-fold form according to an embodiment of the present disclosure.

### Description of the reference signs:

1. Cover plate; 2. First adhesive layer; 3. Polarizer; 4. Display panel; 5. Second adhesive layer; 6. Support layer; 61. First support layer; 62. Second support layer; 63. Third adhesive layer; 6a. First region; 6b. Second region; 6c. Transition region; 71. First concave portion; 72. Second concave portion; 73. Third concave portion; 81. First filling layer; 82. Second filling layer; 83. Third filling layer; 82. Fourth filling layer; 91. First opening; 92. Second opening; 10. Opening pattern; 12. First opening groove; H1. First thickness; H2. Second thickness; H3. Third thickness; W1. First length; X. First direction; Y. Second direction; Z. Third direction.

### DETAIL DESCRIPTION OF EMBODIMENTS

In order to better understand the technical solutions provided by the embodiments of the present disclosure, the technical solutions of the embodiments of the present disclosure are described in detail below with reference to the accompanying drawings and specific embodiments. It should be understood that the embodiments and their specific features of the present disclosure are detailed descriptions of the technical solutions of the embodiments of the present disclosure, and do not limit the technical solutions of the embodiments of the present disclosure. The embodiments and their technical features of the present disclosure may be combined with each other in case of no conflict.

In the present disclosure, relational terms such as first and second, and the like are used solely to distinguish one entity or operation from another without necessarily requiring or implying any actual such relationship or order between such entities or operations. Also, the term “including”, “comprising”, or any other variation thereof, is intended to cover a non-exclusive inclusion, such that a process, method, article, or device that includes a list of elements includes only those elements but also other elements not expressly listed or inherent to such process, method, article, or device. Without further limitation, an element defined by a term “including” does not exclude the presence of other identical elements in the process, method, article, or device that includes the element. Term “more than two” includes two or more.

Terms “x-axis direction”, “y-axis direction” and “z-axis direction” are used, and herein the “x-axis direction” is a first direction X, the “y-axis direction” is a second direction Y perpendicular to the first direction X. The first direction X, the second direction Y and a third direction Z all refer to directions when the flexible display module is placed on a plane and in an unfolded state. The “z-axis direction” is the third direction Z perpendicular to the first direction X and the second direction Y. The first direction (the x-axis direction), the second direction (the y-axis direction), and the third direction (the z-axis direction) may correspond to a thickness direction, a vertical direction, and a horizontal direction of the flexible display module, respectively.

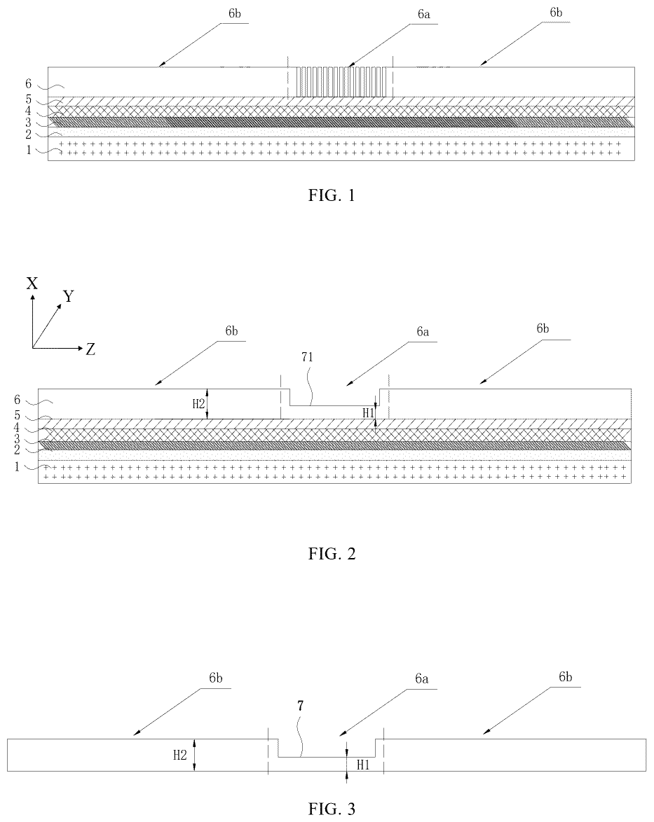

FIG. 1 is a cross-sectional view of a structure of a flexible display module in the related art. As shown in FIG. 1, a flexible display module includes a cover plate 1, a first adhesive layer 2, a polarizer 3, a display panel 4, a second adhesive layer 5, and a support layer 6, which are provided in a stacked mode. The support layer 6 includes a first region 6a and a second region 6b arranged on opposite sides of the first region 6a. The first region 6a corresponds to a first foldable region of the display panel 4, and the second region 6b corresponds to a first non-foldable region and a second non-foldable region of the display panel 4. In the related art, in order to improve the bending performance of the flexible display module, a plurality of through holes are arranged in the first region 6a of the support layer 6, so that the first region 6a of the support layer 6 meets the bending requirement of the flexible display module while the support layer 6 can play a supporting role. However, the plurality of through holes penetrate through the support layer 6, so that the flexible display module is bent several times, which easily causes the lines made by folding and the crack of the support layer 6; the mechanical strength of the flexible display module is adversely affected and an imprint by attaching is caused in a first bending region of the display panel 4 when the support layer 6 is attached with the display panel 4.

FIG. 2 is a cross-sectional view of a structure of a flexible display module according to an embodiment of the present disclosure; FIG. 3 is a schematic diagram of a structure of a support layer of the flexible display module. As shown in FIGS. 2 and 3, the support layer 6 has a first concave portion 71 in the first region 6a. In a first direction X, a first thickness H1 (a first distance H1) exists between a bottom of the first concave portion 71 and a side of the support layer 6 where the first concave portion 71 is not provided in the first region 6a, and the second region 6b of the support layer 6 has a second thickness H2, and the first thickness H1 is less than the second thickness H2. The first direction X is a thickness direction of the display panel 4.

For example, the first thickness H1 is ⅕ to ½ of the second thickness H2. Specifically, the first thickness H1 may be ⅕, ¼, ⅓ or ½ of the second thickness H2. In the process in which the flexible display module is bent, the remaining portion of the support layer 6 with the first thickness H1 in the first region 6a may satisfy the support performance of the support layer 6. Additionally, the support layer 6 in the first region 6a is still an entirety with the first concave portion 71, so that the bending performance of the support layer 6 can be effectively improved, the crack for the support layer 6 after the flexible display module is bent several times can be prevented, and a dustproof effect can be achieved compared with the case where the plurality of through holes are provided in the first region 6a.

For example, the first concave portion 71 may be disposed on a side of the support layer 6 away from the display panel 4. Alternatively, the first concave portion 71 may be disposed on a side of the support layer 6 close to the display panel 4, which is not particularly limited in the embodiment of the present disclosure.

For example, a shape of a cross section of the first concave portion 71 may be a rectangle or a square, in which case the first thickness H1 is a distance between a bottom edge of the rectangle or the square and the side of the support layer 6 where the first concave portion 71 is not provided in the first direction X. Alternatively, the shape of the cross section of the first concave portion 71 may be a half circular arc, in which case the first thickness H1 is a distance between a bottom point of the circular arc and the side of the support layer 6 where the first concave portion 71 is not provided in the first direction X. Alternatively, the shape of the cross section of the first concave portion 71 may be an inverted trapezoid, in which case the first thickness H1 is a distance between a bottom edge of the inverted trapezoid and the side of the support layer 6 where the first concave portion 71 is not provided in the first direction X. Alternatively, the shape of the cross section of the first concave portion 71 may be a curved quadrilateral, in which case the first thickness H1 is a distance between a bottom edge of the quadrilateral and the side of the support layer 6 where the first concave portion 71 is not provided in the first direction X. It should be noted that the shape of the cross section of the first concave portion 71 is not particularly limited in the embodiment of the present disclosure, as long as the first thickness H1 of the first region 6a of the support layer 6 is at least partially less than the second thickness H2 of the second region 6b.

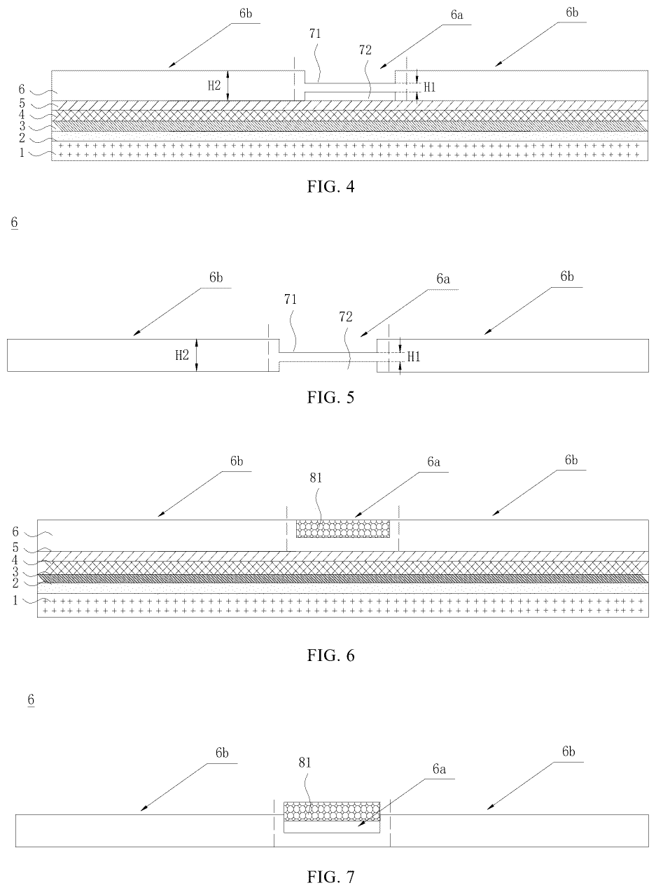

In one possible embodiment, as shown in FIGS. 4 and 5, the support layer 6 further includes a second concave portion 71 corresponding to the first concave portion 71 and arranged in the first region 6a. In this case, the first thickness H1 is a distance between the first concave portion 71 and the second concave portion 72 in the first direction X. For example, the first thickness H1 is ⅕ to ½ of the second thickness H2. Specifically, the first thickness H1 may be ⅕, ¼, ⅓ or ½ of the second thickness H2.

For example, the shape of the cross section of the first concave portion 71 and a shape of a cross section of the second concave portion 72 may be equal to each other. Alternatively, the shape of the cross section of the first concave portion 71 and the shape of the cross section of the second concave portion 72 may be different from each other, which is not particularly limited in the embodiment of the present disclosure.

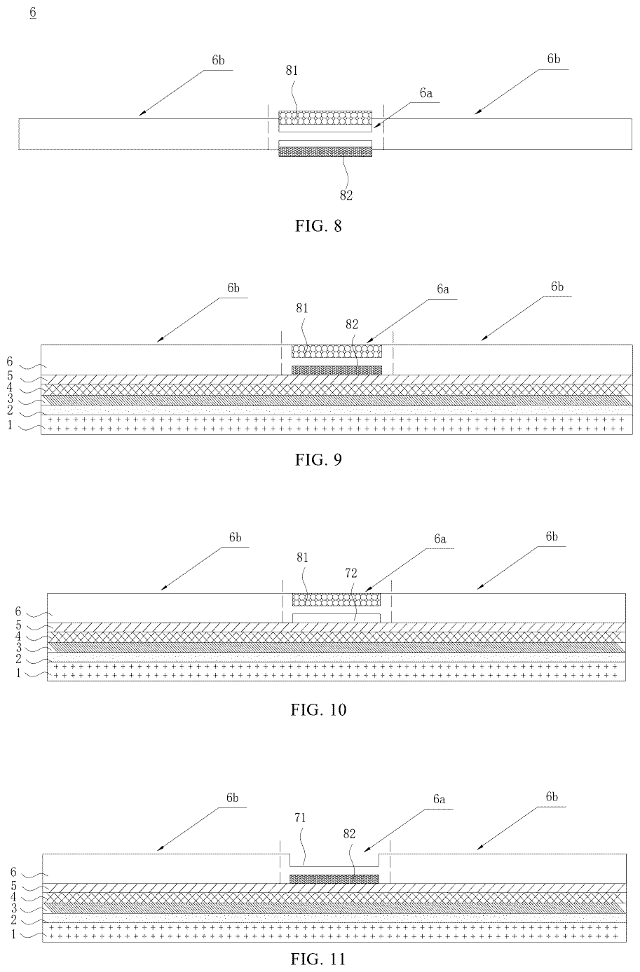

FIG. 6 is a cross-sectional view of another structure of a flexible display module according to an embodiment of the present disclosure; FIGS. 7 and 8 are schematic diagrams of another structure of a support layer according to an embodiment of the present disclosure. As shown in FIGS. 6 to 8, the support layer 6 further includes a first filling layer 81 disposed in the first concave portion 71. Optionally, as shown in FIG. 8, the support layer 6 further includes a second filling layer 82 disposed in the second concave portion 72. When frictions are produced between the flexible display module and hinges of a complete machine in the process in which the flexible display module is bent, the first filling layer 81 and the second filling layer 82 can effectively play the cushioning effect, thereby reducing the risk of the crack for the support layer 6.

In one possible embodiment, as shown in FIG. 9, the flexible display module may be folded inward. When the flexible display module is folded inward, a display surface of the first non-foldable region and a display surface of the second non-foldable region are relatively close to each other. In this case, the first concave portion 71 may be disposed on a side of the support layer 6 away from the display panel 4, and a material of the first filling layer 81 may be selected from a pressure sensitive adhesive, an optical adhesive, or a foam, or the like. By filling the first filling layer 81 made of the material such as the pressure sensitive adhesive, the optical adhesive or the foam in the first concave portion 71, on one hand, the bending performance of the support layer 6 is ensured, and the risk of the crack for the support layer 6 is reduced, and on the other hand, the first filling layer 81 can enable the side of the support layer 6, where the first concave portion 71 is provided, to be a plane, so that the problem of the imprint possibly generated by the first concave portion 71 is effectively avoided.

Optionally, the flexible display module may be folded outwards. When the flexible display module is folded outwards, the display surface of the first non-foldable region is arranged to face the outside of the folded module, and the display surface of the second non-foldable region deviates from (faces in a different direction from) the display surface of the first non-foldable region. In this case, the first concave portion 71 may be disposed on a side of the support layer 6 away from the display panel 4, and the material of the first filling layer 81 may be PI (polyimide), or PET (polyethylene terephthalate), or the like.

With reference to FIG. 9, the flexible display module may be folded inward, the second concave portion 72 may be disposed on a side of the support layer 6 close to the display panel 4, and the material of the second filling layer 82 may be PI (polyimide), or PET (polyethylene terephthalate), or the like. By filling the second filling layer 82 made of the material such as the PI or the PET in the second concave portion 72, the support performance of the first region 6a of the support layer 6 can be improved, the lines made by folding after the flexible display module is bent several times can be avoided, and the performance for pen-falling and ball-falling of the flexible display module can be improved.

Optionally, as shown in FIG. 9, the first filling layer 81 and the second filling layer 82 are provided in the support layer 6 at the same time. Alternatively, as shown in FIG. 10, the support layer 6 may be provided with only the first filling layer 81. Alternatively, as shown in FIG. 11, the support layer 6 may be provided with only the second filling layer 82, which is not particularly limited in the embodiment of the present disclosure.

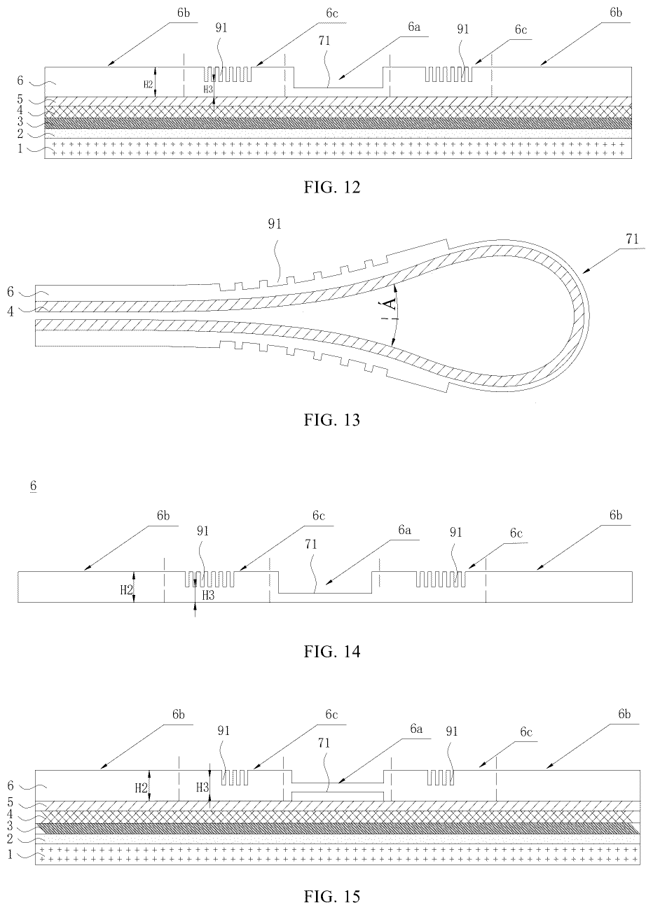

FIG. 12 is a cross-sectional view of another structure of a flexible display module according to an embodiment of the present disclosure; FIG. 13 is a schematic diagram of the bent flexible display module. As shown in FIGS. 12 and 13, the support layer 6 further includes a transition region 6c between the first region 6a and the second region 6b. Referring to FIG. 14, the transition region 6c has first openings 91, and in the first direction X, a third thickness H3 (a third distance H3) exists between a bottom of each first opening 91 and a side of the support layer 6 where the first opening 91 is not provided in the transition region 6c. The third thickness H3 is ½ to ⅔ of the second thickness H2. Optionally, the third thickness H3 may be ½, ⅗ or ⅔ of the second thickness H2.

For example, as shown in FIG. 12 and FIG. 15, the first openings 91 may be disposed on a side of the support layer 6 away from the display panel 4, so as to facilitate releasing stress during the flexible display module is bent, thereby improving the bending performance of the flexible display module.

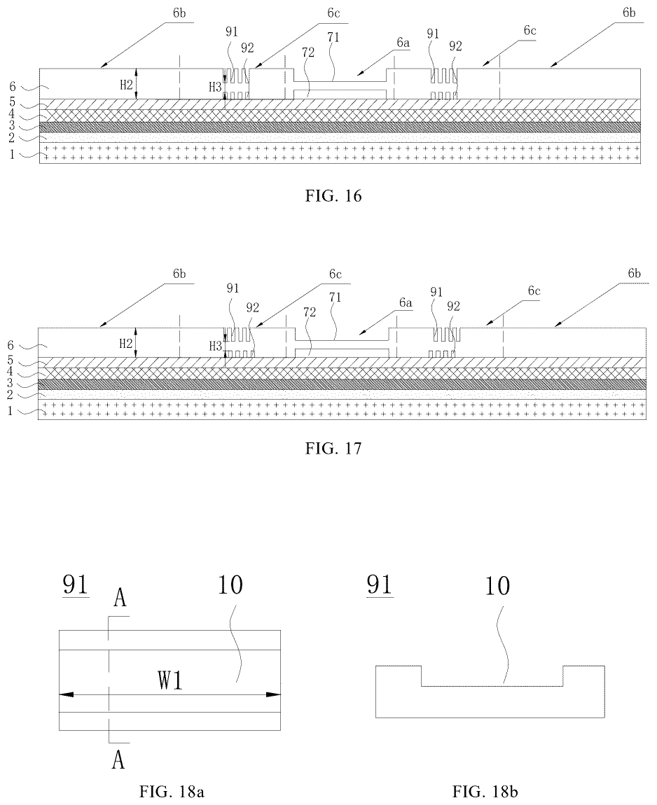

In one possible embodiment, as shown in FIGS. 16 and 17, the support layer 6 further includes second openings 92 arranged in the transition region 6c and corresponding to (in one-to-one correspondence with) the first openings 91. In this case, the third thickness H3 is a distance between the bottom of each first opening 91 and a bottom of the corresponding second opening 92 in the first direction X. The third thickness H3 is ½ to ⅔ of the second thickness H2. Optionally, the third thickness H3 may be ½, ⅗ or ⅔ of the second thickness H2. The first openings 91 and the second openings 92 are respectively arranged on opposite sides of the support layer 6, effectively eliminating the difference in the deformation quantity on opposite sides of the support layer 6 during the flexible display module is bent. In addition, the second openings 92 are arranged on a side of the support layer 6 close to the display panel 4, which may provide certain bending shifting to the bending of the support layer 6, avoid the separation and crack for the layers at the transition region 6c and in a water droplet form from being, thereby improving the bending performance of the support layer 6.

For example, as shown in FIG. 16, the first openings 91 and the second openings 92 corresponding to each other are symmetrically disposed in the first direction X in the transition region 6c. Alternatively, as shown in FIG. 17, the first openings 91 and the second openings 92 are staggered in the first direction X, thereby reducing the modulus of the support layer 6 and improving the bending performance of the support layer.

With continued reference to FIGS. 16 and 17, an orthographic projection of each of the first openings 91 and the second openings 92 on the display panel 4 forms an opening pattern 10. Optionally, the opening pattern 10 formed on the support layer 6 by the first opening 91 may be the same as the opening pattern 10 formed on the support layer 6 by the second opening 92. Alternatively, the opening pattern 10 formed on the support layer 6 by the first opening 91 may be at least partially different from the opening pattern 10 formed on the support layer 6 by the second opening 92, which is not particularly limited in the embodiment of the present disclosure.

Taking the opening pattern 10 of the first opening 91 as an example, FIGS. 18a to 20b are schematic diagrams of a first opening according to an embodiment of the present disclosure, FIGS. 18a, 19a and 20a are schematic diagrams of an orthographic projection of the opening pattern of the first opening on the display panel 4, and FIGS. 18b, 19b and 20b are side views of the first opening. As shown in FIGS. 18a and 18b, the first opening 91 includes the opening pattern 10 extending along a second direction Y, the opening pattern 10 has a first length W1 in the second direction Y, and is formed with an orthographic projection pattern on the display panel 4 (an orthographic projection of the opening pattern 10 on the display panel 4 is formed with a pattern). Optionally, the orthographic projection pattern may be rectangular, wavy, or arc-shaped. Further, a shape of a cross section embodied in each of the side views of the first opening 91 may be rectangular, square, or trapezoidal. The second direction Y is a width direction of the display panel 4, and is perpendicular to the first direction X. It should be noted that the orthographic projection pattern and the shape of the cross section of the first opening 91 are not particularly limited in the embodiment of the present disclosure with meeting the technical requirements.

In one possible embodiment, as shown in FIGS. 18a and 18b, the first opening 91 includes only one opening pattern 10, in which case the first length W1 is the same as a length of the support layer 6 in the second direction Y, i.e., the opening pattern 10 extends throughout the support layer 6 in the second direction Y.

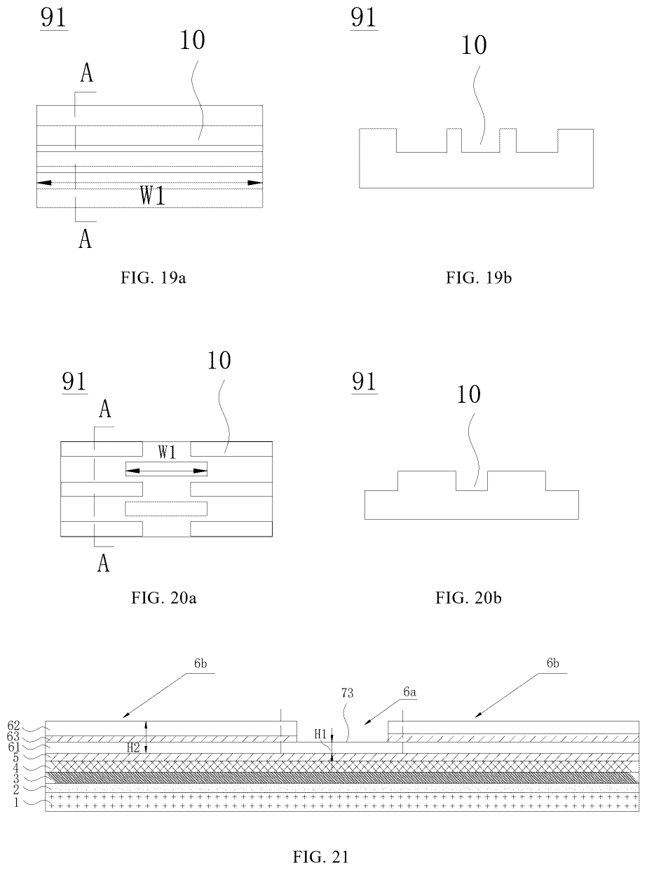

In another possible embodiment, as shown in FIGS. 19a and 19b, the first opening 91 may be composed of a plurality of opening patterns 10, the first length W1 is the same as the length of the support layer 6 in the second direction Y, and the plurality of opening patterns 10 are arranged at intervals in a third direction Z. Optionally, the plurality of opening patterns 10 may be uniformly arranged in the third direction Z. Alternatively, the plurality of opening patterns 10 may be non-uniformly arranged in the third direction Z, where the third direction Z refers to a length direction of the display panel 4, a plane formed by the third direction Z and the second direction Y is parallel to the display panel 4, and the first direction X, the second direction Y, and the third direction Z are perpendicular to each other.

In yet another possible embodiment, as shown in FIGS. 20a and 20b, the first opening 91 may be composed of the plurality of opening patterns 10, and the first length W1 is less than the length of the support layer 6 in the second direction Y. Optionally, the first length W1 is ¼ to ½ of the length of the support layer 6 in the second direction Y. Specifically, the first length W1 may be ¼, ⅓, ⅖, or ½ of the length of the support layer 6 in the second direction Y.

With continued reference to FIGS. 20a and 20b, optionally, the plurality of adjacent opening patterns 10 are staggered in the second direction Y. Alternatively, the plurality of adjacent opening patterns 10 are uniformly arranged in the second direction Y, which is not particularly limited in the embodiment of the present disclosure. FIG. 21 is a cross-sectional view of still another structure of a flexible display module according to an embodiment of the present disclosure. As shown in FIG. 21, the support layer 6 includes a first support layer 61, a second support layer 62, and a third adhesive layer 63, the first support layer 61 is adhered to the display panel 4 by the second adhesive layer 5, and the second support layer 62 is disposed on a side of the first support layer 61 away from the display panel 4 and is adhered to the first support layer 61 by the third adhesive layer 63. With continued reference to FIG. 21, the second support layer 62 has a third concave portion 73 in the first region 6a, so that the first support layer 61 can effectively guarantee the structural strength of the flexible display module, and ensure the support performance of the support layer 6. The second support layer 62 is adhered to the first support layer 61 by the third adhesive layer 63, and the third concave portion 73 is provided in the first region 6a of the second support layer 62, thereby improving the bending performance of the support layer 6 and reducing the risk of the crack for the support layer 6 after the flexible display module is bent several times.

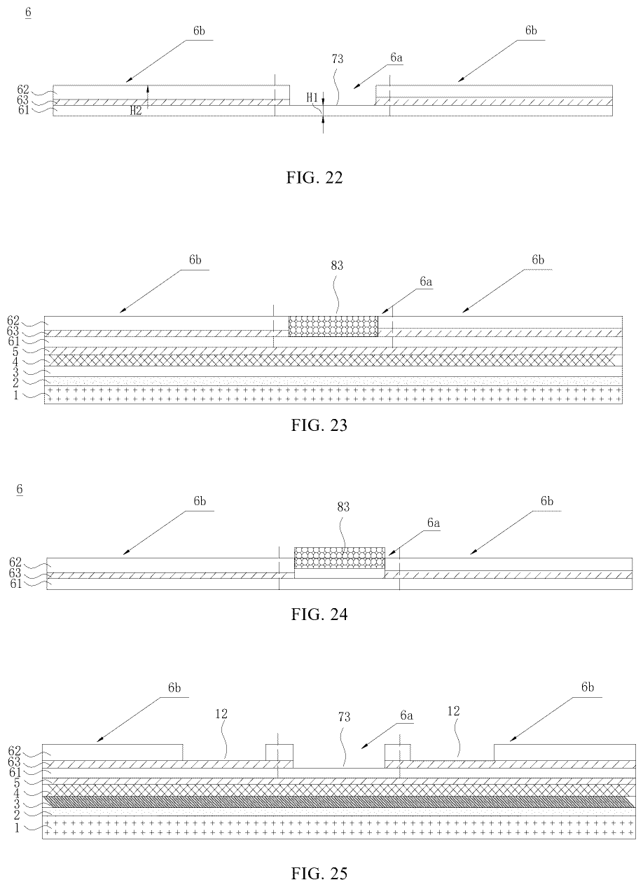

For example, referring to FIG. 22, the third concave portion 73 is disposed on a side of the second support layer 62 away from the first support layer 61. At this time, the first thickness H1 refers to a distance of the first support layer 61 in the first direction X, and the second thickness H2 refers to a distance between a side of the second support layer 62 away from the first support layer 61 and a side of the first support layer 61 close to the display panel 4 in the first direction X.

For example, a shape of a cross section of the third concave portion 73 may be rectangular or square. Alternatively, the shape of the cross section of the third concave portion 73 may be a half circular arc. Alternatively, the shape of the cross section of the third concave portion 73 may be an inverted trapezoidal. Alternatively, the shape of the cross section of the third concave portion 73 may be a curved quadrangle. It should be noted that the shape of the cross section of the third concave portion 73 is not particularly limited in the embodiment of the present disclosure, as long as the first thickness H1 is at least partially less than the second thickness H2.

In one possible embodiment, as shown in FIGS. 23 and 24, the second support layer 62 further includes a third filling layer 83 disposed in the third concave portion 73. Optionally, the flexible display module may be configured to be folded inward, and a material of the third filling layer 83 may be selected from a pressure sensitive adhesive, an optical adhesive, or a foam, or the like. By filling the third filling layer 83 made of the material such as the pressure sensitive adhesive, the optical adhesive or the foam in the third concave portion 73, on one hand, the bending performance of the support layer 6 is ensured, and the risk of the crack for the support layer 6 is reduced, and on the other hand, the third filling layer 83 can enable the side of the support layer 6, where the third concave portion 73 is provided, to be a plane, so that the problem of the imprint possibly generated by providing the third concave portion 73 is effectively avoided.

In another possible embodiment, as shown in FIG. 25, first opening grooves 12 are provided in the second region 6b of the second support layer 62 and symmetrically arranged with respect to the first region 6a of the second support layer 62 in the third direction Z.

For example, a depth of each first opening groove 12 in the first direction X may be the same as the distance of the second support layer 62 along the first direction X. Alternatively, the depth of each first opening groove 12 in the first direction X is only ⅓ to ½ of the distance of the second support layer 62 along the first direction X. Specifically, the depth of each first opening groove 12 in the first direction X is ⅓, 3/10 or ½ of the distance of the second support layer 62 along the first direction X, which is not particularly limited in the embodiments of the present disclosure.

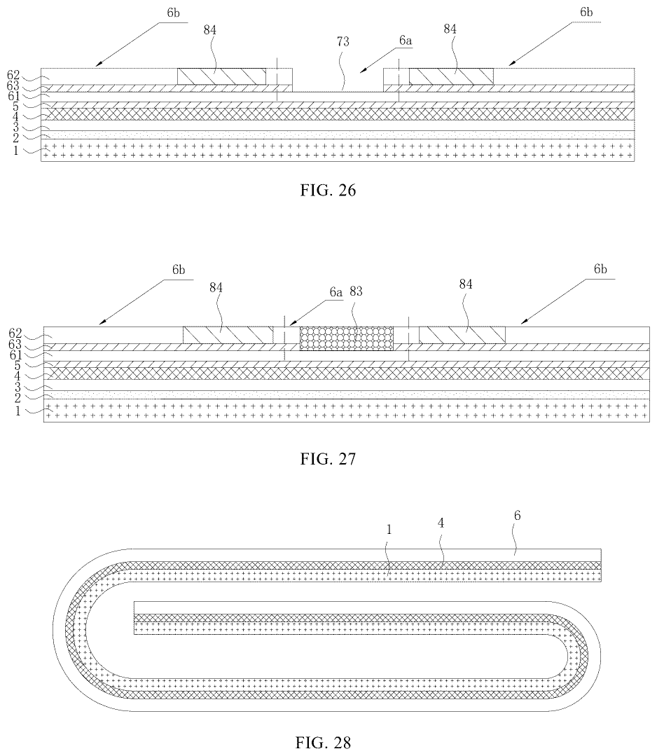

For example, as shown in FIGS. 26 and 27, the second support layer 62 further includes a fourth filling layer 84 disposed in each first opening groove 12. Optionally, the fourth filling layer 84 may be made of a heat dissipation material, specifically, graphite, a heat conductive adhesive, or a copper sheet, or the like. The first opening grooves 12 are formed in the second region 6b of the second support layer 62, and the fourth filling layer 84 is filled in each first opening groove 12, so that the heat conduction performance of the first support layer 61 is improved while the support performance of the first support layer 61 is met, and the heat dissipation performance of the flexible display module is improved.

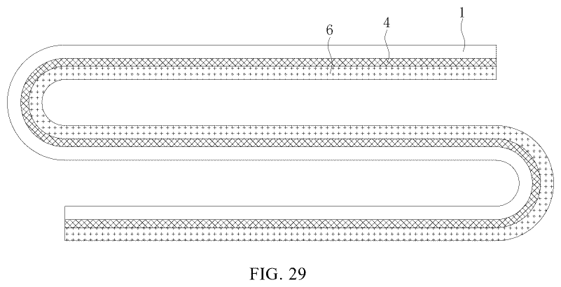

FIGS. 28 and 29 are schematic diagrams of a flexible display module in a three-fold form according to an embodiment of the present disclosure. In one possible embodiment, as shown in FIGS. 28 and 29, the display panel 4 further includes a second foldable region and a third non-foldable region, the second foldable region is located between the second non-foldable region and the third non-foldable region. Optionally, a width of the first foldable region is greater than that of the second foldable region in the third direction Z.

For example, the display panel 4 is folded at a first radius of curvature in the first foldable region and folded at a second radius of curvature in the second foldable region. Optionally, the first radius of curvature in the first foldable region is greater than the second radius of curvature in the second foldable region.

For example, the support layer 6 further has a third region corresponding to the second foldable region of the display panel 4. The third region further has a fourth concave portion, and in the first direction X, a fourth thickness (a fourth distance) exists between a bottom of the fourth concave portion and a side of the support layer 6 where the fourth concave portion is not provided in the third region. The fourth thickness is less than the second thickness H2 and the first thickness H1.

Optionally, the first concave portion 71 is disposed on a side of the support layer 6 away from the display panel 4. The fourth concave portion is disposed on a side of the support layer 6 away from the display panel 4.

Optionally, the support layer 6 further includes the first filling layer 81 and/or a fifth filling layer, the first filling layer 81 is disposed in the first concave portion 71, the fifth filling layer is disposed in the fourth concave portion, and a modulus of the first filling layer is greater than that of the fifth filling layer.

Optionally, as shown in FIG. 28, the first foldable region is folded inward, and the second foldable region is also folded inward, so that the display panel 4 is folded in a “G” shape. Materials of the first filling layer 81 and the fifth filling layer may be selected from a pressure sensitive adhesive, an optical adhesive, or a foam, or the like. By filling the first filling layer 81 made of the material such as the pressure sensitive adhesive, the optical adhesive or the foam in the first concave portion 71 and/or filling the fifth filling layer made of the material such as the pressure sensitive adhesive, the optical adhesive or the foam in the fourth concave portion, on one hand, the bending performance of the support layer 6 is ensured, and the risk of the crack for the support layer 6 is reduced, and on the other hand, the first filling layer 81 and/or the fifth filling layer can enable the side of the support layer 6, where the first concave portion 71 and/or the fourth concave portion is provided, to be a plane, so that the problem of the imprint possibly generated by the first concave portion 71 and/or the fourth concave portion is effectively avoided.

Optionally, as shown in FIG. 29, the first foldable region is folded outward, and the second foldable region is folded inward, and the display panel is folded in a “Z” shape. The material of the first filling layer 81 may be selected from PI (polyimide), or PET (polyethylene terephthalate), or the like. The material of the fifth filling layer may be selected from a pressure sensitive adhesive, an optical adhesive, or a foam or the like.

For example, the display panel 4 may be folded in the “G” shape or in the “Z” shape, which is not specifically limited in the embodiment of the present disclosure, and may be selected by one of ordinary skill in the art according to actual needs.

In one possible embodiment, a flexible display apparatus is further provided, where the flexible display apparatus includes a flexible display module, which may be the flexible display module having the support layer 6 in any one of the above embodiments. The flexible display module includes a cover plate 1, a first adhesive layer 2, a polarizer 3, a display panel 4, a second adhesive layer 5 and a support layer 6. The support layer 6 is capable of supporting the display panel 4, and the cover plate 1 is capable of protecting the display panel 4.

For example, the cover plate 1 may be a single-layer structure or a stacked multi-layer structure. When the cover plate 1 is a single-layer structure, the cover plate 1 may be made of an organic material having a high light transmittance, such as polyimide (PI), polyethylene terephthalate (PET), or colorless polyimide (CPI), so as to ensure the light transmittance, the protection for the cover plate 1, and the bendability of the cover plate.

When the cover plate 1 is a stacked multi-layer structure, the cover plate 1 may include a first organic layer, an inorganic layer, and a second organic layer, which are sequentially stacked, the first organic layer and the second organic layer may be made of polyimide (PI), polyethylene terephthalate (PET), or polyimide (CPI), or the like, and the inorganic layer may be a glass layer. Optionally, the inorganic layer may be an ultra-thin glass layer (UTG), or an ultra-thin glass layer having different thicknesses (i.e., ultra flexible glass (UFG)), or the like. These materials may fulfill the protection for the flexible display panel 4.

For example, the first adhesive layer 2 is made of the optical adhesive, and the polarizer 3 is adhered to the cover plate 1 through the first adhesive layer 2.

For example, the display panel 4 includes, but is not limited to, an OLED (organic light emitting diode) display panel, or a QLED (quantum dot light emitting diode) display panel, or the like, which is not limited in the embodiment of the present disclosure.

For example, the support layer 6 may be made of a metal material with a great elastic modulus, such as SUS (stainless steel), steel sheet, or titanium (Ti), or the like; or a non-metal material, such as carbon fiber reinforced plastics (CFRP), or glass fiber reinforced plastics, or the like; or a combination of the metal material and the non-metal material. The support layer 6 is made of the carbon fiber reinforced plastics, so that a weight of the support layer 6 can be effectively reduced, and the lightweight design of the flexible display module is further realized while the support for the flexible display module is met.

For example, the second adhesive layer 5 is a whole layer structure. Optionally, the second adhesive layer 5 is made of a pressure sensitive adhesive or an optical adhesive. These materials may fulfill the adhesive function without affecting the display function of the flexible display panel 2.

For example, the third adhesive layer 63 is made of a pressure sensitive adhesive or an optical adhesive, so that the support performance of the first support layer 61 and the second support layer 62 is not be affected while the adhesive function is met.

For example, the flexible display apparatus provided in the embodiment of the present disclosure may be applied to a smart phone, a tablet computer, a display, a notebook computer, a medical display, a television, an intelligent wearable display, and other scenes, which is not particularly limited in the embodiment of the present disclosure.

The flexible display apparatus has the same technical effect as the flexible display module, which is not described again.

It should be noted that the description for the above embodiments places different emphases on the embodiments, and reference may be made to the related description of other embodiments for a part that is not described in detail in a certain embodiment.

The above embodiments are only used to illustrate, not limit, the technical solutions of the present disclosure. The present disclosure has been described in detail with reference to the above embodiments, but it should be understood by one of ordinary skill in the art that the technical solutions described in the above embodiments may still be modified, or some technical features may be equivalently replaced by one of ordinary skill in the art. Such modifications or replacements do not cause the essence of the corresponding technical solutions to depart from the spirit and scope of the technical solutions of the embodiments of the present disclosure.

While the preferred embodiments of the present disclosure have been described, additional variations and modifications in these embodiments may occur to one of ordinary skill in the art once they learn of the basic inventive concepts. Therefore, the appended claims are intended to be interpreted as including the preferred embodiments and all changes and modifications that fall within the scope of the present disclosure.

It will be apparent to one of ordinary skill in the art that various changes and modifications can be made in the present disclosure without departing from the spirit and scope of the present disclosure. Thus, if such changes and modifications of the present disclosure fall within the scope of the claims and their equivalents of the present disclosure, such changes and modifications are also intended to be included in the present disclosure.

1. A flexible display module, comprising:
a cover plate;
a display panel, comprising a first non-foldable region, a first foldable region, and a second non-foldable region, wherein the first non-foldable region and the second non-foldable region are on opposite sides of the first foldable region;
a first adhesive layer between the cover plate and the display panel;
a second adhesive layer on a side of the display panel away from the cover plate; and
a support layer on a side of the second adhesive layer away from the display panel, wherein the support layer comprises a first region corresponding to the first foldable region of the display panel and a second region on opposite sides of the first region, the first region at least partially has a first thickness, and the second region at least partially has a second thickness;
wherein the first thickness is less than the second thickness in a first direction, and the first direction is perpendicular to a plane where the display panel is located.

2. The flexible display module of claim 1, wherein the first region comprises a first concave portion.

3. The flexible display module of claim 2, wherein the first region further comprises a second concave portion on a side of the support layer, opposite to the side where the first concave portion is located, in the first direction.

4. The flexible display module of claim 3, wherein
a distance between a bottom of the first concave portion and a surface of the support layer away from the first concave portion in the first direction is the first thickness; or
a distance between the bottom of the first concave portion and a bottom of the second concave portion in the first direction is the first thickness;
the first thickness is greater than or equal to one fifth of the second thickness in the first direction; and
the first thickness is less than or equal to one half of the second thickness in the first direction.

5. (canceled)

6. The flexible display module of claim 2, further comprising a first filling layer in the first concave portion and/or a second filling layer in the second concave portion.

7. (canceled)

8. The flexible display module of claim 6, wherein the first foldable region is folded inward, the first concave portion is on a side of the support layer away from the display panel, and the first filling layer has a material of one or more of a pressure sensitive adhesive, an optical adhesive and a foam; and
the first foldable region is folded toward the second concave portion is on a side of the support layer close to the display panel, and the second filling layer bas a material of one or more of polyimide and polyethylene terephthalate.

9. (canceled)

10. The flexible display module of claim 2, wherein the support layer further comprises a transition region between the first region and the second region; and
the transition region comprises first openings therein, and an orthographic projection of each first opening on the support layer forms an opening pattern.

11. The flexible display module of claim 10, wherein a distance between a bottom of each first opening and a side of the support layer away from each first opening in the first direction is a third thickness;
the third thickness is greater than or equal to one half of the second thickness in the first direction; and
the third thickness is less than or equal to two thirds of the second thickness in the first direction.

12. The flexible display module of claim 10, wherein the transition region further comprising second openings on a side opposite to the side where the first openings are located, and an orthographic projection of each second opening on the support layer forms an opening pattern:
a distance between the bottom of each first opening and a bottom of a second opening corresponding to the first opening in the first direction is a third thickness.
the third thickness is greater than or equal to one half of the second thickness in the first direction; and
the third thickness is less than or equal to two thirds of the second thickness in the first direction, and
the orthographic projection of each first opening on the support layer and the orthographic projection of each second opening on the support laver form the same opening pattern.

13-14. (canceled)

15. The flexible display module of claim 10, wherein the orthographic projection of each first opening on the support layer forms at least one opening pattern, which has a shape from one or more of a rectangular shape, a wavy shape and an arc shape; and
a cross section of each first opening bas a shape from one or more of a rectangular shape, a square shape, and a trapezoidal shape.

16. (canceled)

17. The flexible display module of claim 15, wherein the at least one opening pattern each extends along a second direction and has a first length in the second direction, and every two adjacent opening patterns are spaced apart from each other in a third direction.

18. The flexible display module of claim 17, wherein the first length is equal to a length of the support layer in the second direction, or
the first length is greater than or equal to one quarter of a length of the support layer in the second direction, and the first length is less than or equal to one half of the length of the support layer in the second direction.

19. (canceled)

20. The flexible display module of claim 12, wherein the first opening and the second opening corresponding to each other are symmetrical in the first direction, or
the first openings and the second openings are staggered in the first direction.

21. (canceled)

22. The flexible display module of claim 1, wherein the support layer comprises a first support layer, a second support layer, and a third adhesive layer, the second support layer is on a side of the first support layer away from the display panel, and the second support layer is adhered to the first support layer by the third adhesive layer; and
the first region comprises a third concave portion therein on a side of the second support laver away from the first support laver.

23. (canceled)

24. The flexible display module of claim 22, wherein
a distance between a surface of the second support layer away from the first support layer and a surface of the first support layer close to the display panel in the first direction is the second thickness, and
the flexible display module further comprises a third filling layer in the third concave portion;
wherein the first foldable region is folded inwards, and the third filling laver is made of one or more of a pressure sensitive adhesive an optical adhesive and a foam.

25. (canceled)

26. The flexible display module of claim 24, wherein the second region of the second support layer comprises first opening grooves, which are arranged symmetrical with respect to the first region in a third direction; and
the flexible display module further comprises a fourth filling layer in the first opening grooves, wherein the fourth filling layer is made of one or more of graphite, a beat conductive adhesive, and a copper sheet.

27. (canceled)

28. The flexible display module of claim 4, wherein the display panel further comprises a second foldable region and a third non-foldable region, the second foldable region is between the second non-foldable region and the third non-foldable region, and the first foldable region has a width greater than that of the second foldable region in a third direction; and
the support layer comprises a third region corresponding to the second foldable region, the third region at least partially has a fourth thickness, and the fourth thickness is less than the second thickness in the first direction and
the third region comprises a fourth concave portion therein, and a distance between a bottom of the fourth concave portion and a surface of the support layer away from the fourth concave portion in the first direction is the fourth thickness: and
the first thickness is greater than the fourth thickness in the first direction.

29. (canceled)

30. The flexible display module of claim 28, wherein the display panel is folded with a first radius of curvature in the first foldable region;
the display panel is folded with a second radius of curvature in the second foldable region; and
the first radius of curvature is greater than the second radius of curvature; and
the flexible display module further comprises.
a first filling laver in the first concave portion, wherein the first concave portion is on a side of the support laver away from the display panel; and
a fifth filling layer in the fourth conc: portion, wherein the fourth concave portion is on a side of he support layer away from the display panel;
wherein a modulus of the first filling layer is greater than that of the fifth filling layer.

31. (canceled)

32. The flexible display module of claim 1, further comprising:
a polarizer on a side of the display panel away from the support layer.

33. A flexible display apparatus, comprising the flexible display module of claim 1.
